(19) United States
(12) Patent Application Publication
(10) Pub. No.: US 2009/0135552 A1
(43) Pub. Date: May 28, 2009

(54) HEAT DISSIPATING DEVICE AND HEAT SINK FASTENER

(75) Inventors: Kun Feng Tu, Taipei (TW); Ying Lin Hsu, Taipei (TW); Tsung Hsi Yu, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: COOLER MASTER CO., LTD., Taipei (TW)

(21) Appl. No.: 12/265,121

(22) Filed: Nov. 5, 2008

(30) Foreign Application Priority Data
Nov. 28, 2007 (TW) 096220086

(51) Int. Cl. H05K 7/20

(52) U.S. Cl. 361/676

(57) ABSTRACT

A heat dissipating device is disclosed. The heat dissipating device comprises a heat dissipating base, a frame and at least one resilient member. The heat dissipating base has a plate, and at least one hole is formed on the plate. The frame has at least one protruding column, and at least one side of the frame has a protrusion. The resilient member is put on the protruding column correspondingly. When the frame buckles an edge of the plate by the protrusion and be put on the heat dissipating base, the protruding column can pass through the hole on the plate to make the frame elastically associate with the heat dissipating base through the resilient member. Thus, the heat dissipating device makes the heat dissipating base keep closer contact with a chip, balances internal stresses, prevents hestsinks design from being restricted, and further lowers cost.

### BACKGROUND OF THE INVENTION

1. Field of the invention

The invention relates to a heat dissipating device, and more particularly, to a heat sink fastener for fixing a heat dissipating base on a chip.

2. Description of the prior art

In recent years, with the rapid development of IC technology, the requirement for 3C products is gradually growing. Due to trends toward miniaturization and high-performance, the system has more powerful functions and the chip also has multi-functions so that users can process several functions at the same time to meet the consumer's needs. As a result, more transistors are contained in the confined area of the chip to achieve better performance, which causes the increasing of the heat density of the chip. However, according to the reference documents, 55% of electrical element failure is caused by the high temperature factor. And, when the temperature of the electrical element grows 10□, the reliability will lower 50%. Therefore, under the increasing of the heat density of the electrical element, the heat dissipating problem of the chip processor has become an important issue and a main developing direction of the product design.

In order to solve the heat dissipating problem, various heat dissipating devices are used to prevent the temperature of the electrical element from increasing. In general, the so-called heat dissipating device comprises fans and metal materials with high heat conducting coefficient of Al or Cu. The basic design concept of heat dissipating module is to transfer the heat generated from the chip to the rear of the metal by tightly adhering the metal materials with high heat conducting coefficient on the surface layer of the chip, and then fans are used to keep the chip operate under a fixed work temperature by a convection way. It is identical to a radiator system in a car, a heat dissipating system of an air-conditioner, and a larger fan for increasing the frequency of a desktop computer. But, the difference among the various applications is that the heat conducting module in the chip should be specially designed to maintain the convection and conductivity in the confined space of the chip.

In general, a fastener is used to fix a heat dissipating base on a chip so that the heat dissipating base made by the metal materials with high heat conducting coefficient can be tightly adhered onto the surface layer of the chip to improve the heat dissipating efficiency, as shown in the patent TW449250.

Please refer to FIG. 1. FIG. 1 shows an explode drawing of the fastener 1′ with the heat dissipating base 2′ and the chip 3′ in prior art. As shown in FIG. 1, the heat dissipating base 2′ has a rectangle plate 21′, a plurality of fins 22′ are formed on the rectangle plate 21′, and a sink 24′ which can contain the width of a rectangle frame of the fastener 1′ is formed on the fin 22′. In addition, because the pin of the chip 3′ soldered on a circuit board 4′ has a height, there will be an appropriate space between the chip 3′ and the circuit board 4′. Therefore, when fabricating, the fin 22′ of the heat dissipating base 2′ is put on the fastener 1′ upward to make the rectangle plate 21′ of heat dissipating base 2′ buckle an edge of the fastener 1′, and then the hooks 111′ on two sides of the fastener 1′ are forced to buckle two corresponding edges 31′ of the chip 3′. After a protruding column passes through a hole 23′ pre-formed on the sink 24′ of the heat dissipating base 2′ to make a protrusion 131′ under a resilient rod 13′ elastically associate with the heat dissipating base 2′, the fabricating can be rapidly finished. On the contrary, in order to remove the fin 22′, the only thing needed to do is to pull the fastener 1′ upward to make the hooks 111′ separate from the buckling of the chip 3′. Therefore, the total fabrication efficiency can be improved.

However, the conventional heat sink fasteners have many drawbacks described as follows:

The distribution of the stress provided to fix the heat dissipating base 2′ on the chip 3′ is not uniform.

Because the fastener 1′ of FIG. 1 uses its own material stress and the buckling pressure of the protruding column to fix the heat dissipating base 2′ on the chip 3′, the inaccuracy resulted in manufacturing process of the fastener 1′ will easily cause the nonuniformity of the stress when pressing. Especially, when one point or one side of the fastener 1′ is pressed, the connection between the heat dissipating base 2′ and the chip 3′ will be seriously affected.

The fabrication cost is high.

The design of the fastener in prior art will be varied for different heat dissipating bases and different chip thickness. In other words, once the heat dissipating base and the chip thickness are different, the design of the fastener must be changed accordingly, and then the developing and manufacturing cost will be increased.

The arrangement of the heat dissipating fins is limited.

The fastener 1′ in prior art uses the protrusion 131′ under the resilient rod 13′ to elastically associate with the heat dissipating base 2′ to finish the fabrication. However, the design of the resilient rod 13′ will limit the arrangement of the heat dissipating fins 22′. For example, the sink 24′ on the fin 22′ is added to meet the design of the resilient rod 13′ in prior art. Thus, it will make the design of the heat dissipating base and the fastener more complicated and the manufacturing cost will be increased.

Therefore, the invention provides a heat dissipating device and a heat sink fastener to solve the above-mentioned problems.

### SUMMARY OF THE INVENTION

A scope of the invention is to provide a heat dissipating device and a heat sink fastener. According to the special-designed structure, the heat dissipating base and the chip will be closely fixed to improve the heat dissipating efficiency.

A first embodiment of the invention is a heat dissipating device. The heat dissipating device comprises a heat dissipating base, a frame, and at least one resilient member. The heat dissipating base has a plate, and at least one hole is formed on the plate. The frame has at least one protruding column, and at least one side of the frame has a protrusion. The resilient member is put on the protruding column correspondingly. When the frame buckles an edge of the plate by the protrusion and be put on the heat dissipating base, the protruding column can pass through the hole on the plate to make the frame elastically associate with the heat dissipating base through the resilient member.

Moreover, when the frame buckles an edge of a chip by the protrusion to fix the heat dissipating base on the chip, the resilient member will be pressed to generate an elastic force to make the heat dissipating base and the chip adhere together closely.

Compared to the prior art, the heat dissipating device and the heat sink fastener according to the invention have the following advantages: (1) the heat dissipating base and the chip adhere together more closely; (2) the distribution of the stress is more uniform; (3) the limitation of the design of the heat dissipating fins is eliminated; (4) the manufacturing cost will be lowered.

The advantage and spirit of the invention may be further understood by the following recitations together with the appended drawings.

### BRIEF DESCRIPTION OF THE APPENDED DRAWINGS

FIG. 1 shows an explode drawing of the fastener with the heat dissipating base and the chip in prior art.

FIG. 2 shows an explode drawing of a heat dissipating device and a chip according to an embodiment of the invention.

FIG. 3 shows a three-dimensional diagram of the frame in FIG. 2.

FIG. 4 shows a combination diagram of the heat dissipating device in FIG. 2.

FIG. 5 shows a combination diagram of the heat dissipating device in FIG. 2 in another angle of view.

FIG. 6(A) shows a top view of the heat dissipating device in FIG. 4.

FIG. 6(B) shows a cross-sectional diagram of the heat dissipating device in FIG. 6(A) along the A-A line.

FIG. 7 shows a cross-sectional diagram of the combination of the heat dissipating device and the chip in FIG. 6(B).

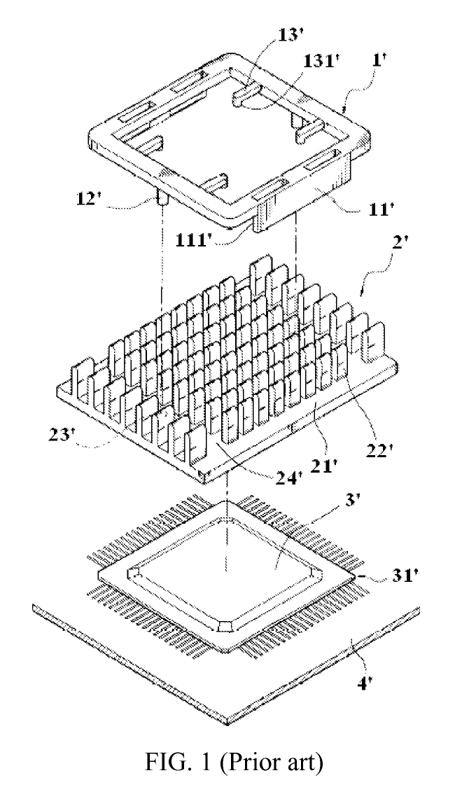

### DETAILED DESCRIPTION OF THE INVENTION

The invention provides a heat dissipating device and a heat sink fastener. According to the designed special structure, the heat dissipating base and the chip will be closely fixed to improve the heat dissipating efficiency.

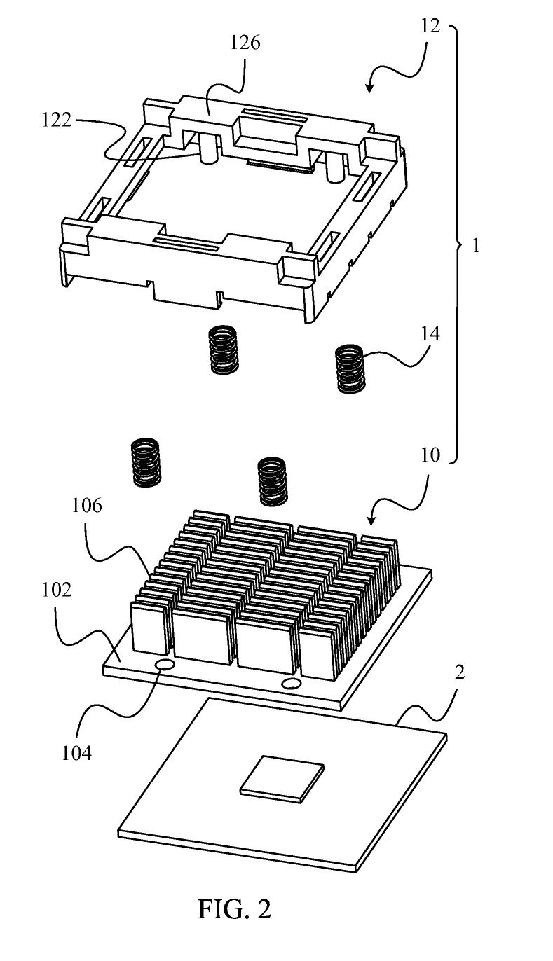

A first embodiment according to the invention is a heat dissipating device. Please refer to FIG. 2. FIG. 2 shows an explode drawing of a heat dissipating device and a chip. As shown in FIG. 2, a heat dissipating device 1 is used for keeping close contact with a chip 2 to increase the heat dissipating efficiency. In this embodiment, the heat dissipating device 1 comprises a heat dissipating base 10, a frame 12, and four resilient members 14. It should be indicated that the amount of the resilient members 14 can depend on the practical applications; it is not limited to the four members shown in FIG. 2.

In addition, the heat dissipating base 10 has a plate 102, and four holes 104 are formed on the plate 102 (FIG. 2 only shows two holes 104 due to the angle of view). The plate 102 has a plurality of heat dissipating fins 106 in parallel order. The frame 12 has four protruding columns 122 (FIG. 2 only shows two protruding columns 122 due to the angle of view) corresponding to the four resilient members 14 and the four holes 104 respectively. The resilient member 14 is put on the protruding column 122 correspondingly.

In practical applications, the resilient member 14 can be a spring or any other similar member. It should be indicated that the protruding column 122 is perpendicular to a plane 126 of the frame 12 so that the resilient member 14 is capable of expanding and contracting in the directions perpendicular to the plane 126.

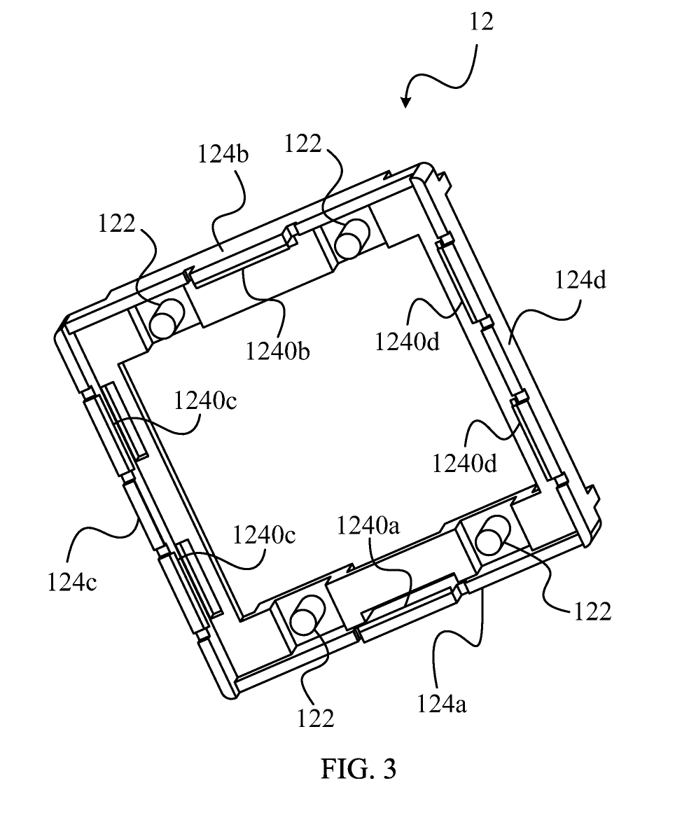

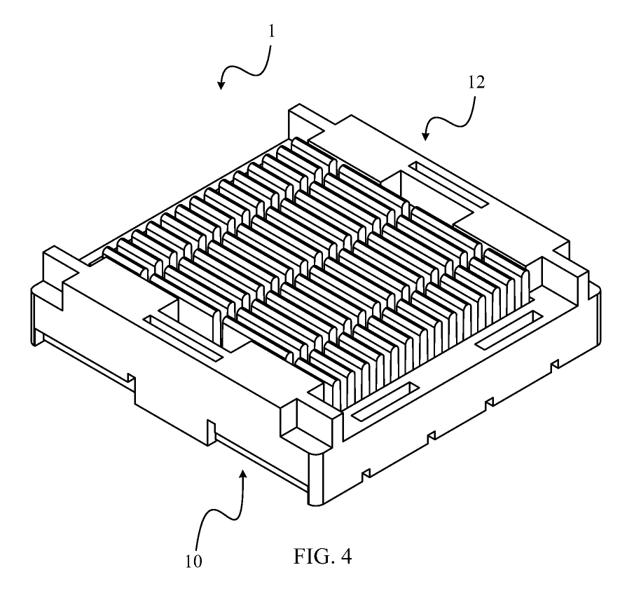

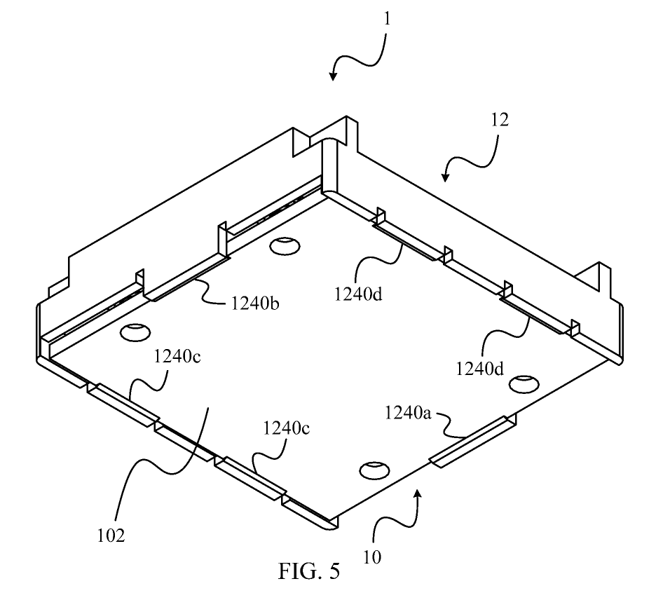

As shown in FIG. 3, the frame 12 has four sides 124a, 124b, 124c, and 124d, wherein the side 124a comprises a protrusion 1240a and the side 124b comprises a protrusion 1240b; the side 124c comprises two protrusions 1240c and 1242c; the side 124d comprises two protrusions 1240d and 1242d. As shown in FIG. 5, when the frame 12 is put on the heat dissipating base 10, the protrusions 1240a, 1240b, 1240c, 1242c, 1240d, and 1242d can buckle the edge of the plate 102 respectively so that the heat dissipating base 10 will be fixed, as shown in FIG. 4 and FIG. 5.

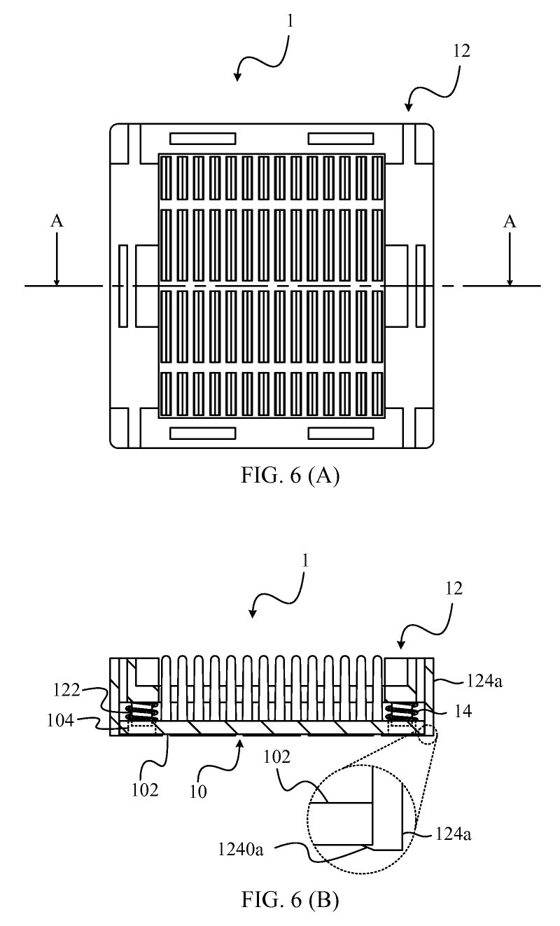

Please refer to FIG. 6(A) and FIG. 6(B), when the frame 12 is put on the heat dissipating base 10 by buckling the edge of the plate 102 via the protrusion 1240a, the protruding column 122 is capable of passing through the hole 104 on the plate 102 correspondingly so that the frame 12 can elastically associate with the heat dissipating base 10 via the resilient member 14.

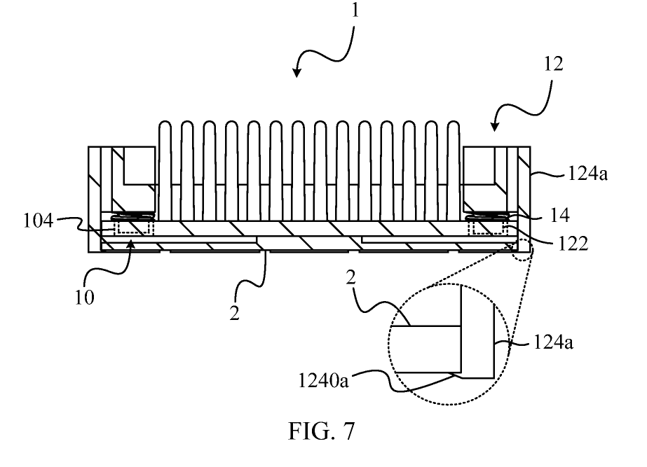

As shown in FIG. 7, when the frame 12 buckles the edge of the plate 102 via the protrusion 1240a, the heat dissipating base 10 will be fixed on the chip 2. Because the resilient member 14 is pressed to generate an elastic force, the heat dissipating base 10 will closely adhere to the chip 2 due to the elastic force.

Compared to the prior art, the heat dissipating device and the heat sink fastener provided by the invention have the following advantages:

The contact between the heat dissipating base 10 and the chip 2 becomes more closely.

The heat dissipating device and the heat sink fastener according to the invention uses the protrusion of the frame to buckle the chip, and the elastic force generated by pressing the resilient member is used to associate with the heat dissipating base. Therefore, the heat dissipating base and the chip will be adhered more closely so that the heat dissipating efficiency can be increased accordingly.

The distribution of the provided stress is uniform.

The drawback that the heat dissipating base can not contact with the chip closely caused by the fabrication error can be improved by using the resilient member to adhere the heat dissipating base to the chip closely. In addition, the position of the resilient member can be properly set up to maintain the entire stress balance when pressing to improve the situation that only one point or one side is pressed.

The arrangement of the heat dissipating fins will be not limited.

In this invention, the protruding columns are located around the frame to make the shape of the protruding columns and the frame be integrated. With the simple structure and the cooperation between the resilient member and the protrusion, the heat dissipating efficiency will be increased without any additional limitation to the design of the heat dissipating fins or adding any structures to the heat dissipating base (e.g., the sink in the prior art). With the design of the invention, the design of the heat dissipating base and the heat sink fastener will become easier and the fabrication cost will be effectively reduced.

The fabrication cost will be reduced.

The heat dissipating base and the heat sink fastener according to the invention use the simple structure to increase the entire heat dissipating efficiency. Moreover, after fabricating, the contact between the heat dissipating base and the chip is maintained by the resilient member, and the resilient member has its own elastic range so that the heat dissipating base and the heat sink fastener can be produced without designing according to the different thickness of the chip. As a result, the cost of designing and fabricating heat dissipating bases and heat sink fasteners according to the invention can be effectively reduced, and the heat dissipating base and the heat sink fastener can be widely used in various different kinds of purposes.

With the recitations of the preferred embodiment above, the features and spirits of the invention will be hopefully well described. However, the scope of the invention is not restricted by the preferred embodiment disclosed above. The objective is that all alternative and equivalent arrangements are hopefully covered in the scope of the appended claims of the invention. Accordingly, the above disclosure should be construed as limited only by the metes and bounds of the appended claims.

What is claimed is:

1. A heat dissipating device, comprising:
a heat dissipating base having a plate, at least one hole being formed on the plate;
a frame having at least one protruding column, at least one side of the frame having a protrusion, the frame being capable of buckling an edge of the plate by the protrusion to be put on the heat dissipating base, the at least one protruding column being capable of passing through the hole on the plate correspondingly; and
at least one resilient member being put on the protruding column correspondingly, the frame being capable of elastically associating with the heat dissipating base via the at least one resilient member.

2. The heat dissipating device of claim 1, wherein the plate of the heat dissipating base has a plurality of heat dissipating fins in parallel order.

3. The heat dissipating device of claim 1, wherein the at least one resilient member is a spring.

4. The heat dissipating device of claim 1, wherein the at least one protruding column is perpendicular to a plane of the frame so that the at least one resilient member is capable of expanding and contracting in the directions perpendicular to the plane.

5. The heat dissipating device of claim 1, wherein the frame is capable of buckling an edge of a chip by the protrusion to fix the heat dissipating base on the chip.

6. A heat sink fastener, applied to fix a heat dissipating base on a chip, the heat dissipating base having a plate, at least one hole being formed on the plate, the heat sink fastener comprising:
a frame having at least one protruding column, at least one side of the frame having a protrusion, the frame being capable of buckling an edge of the chip by the protrusion to fix the heat dissipating base on the chip, the at least one protruding column being capable of passing through the hole on the plate correspondingly; and
at least one resilient member being put on the protruding column correspondingly, the frame being capable of elastically associating with the heat dissipating base via the at least one resilient member.

7. The heat sink fastener of claim 6, wherein the plate of the heat dissipating base has a plurality of heat dissipating fins in parallel order.

8. The heat sink fastener of claim 6, wherein the at least one resilient member is a spring.

9. The heat sink fastener of claim 6, wherein the at least one protruding column is perpendicular to a plane of the frame so that the at least one resilient member is capable of expanding and contracting in the directions perpendicular to the plane.
